(19) United States
(12) Patent Application Publication
(10) Pub. No.: US 2016/0254433 A1
(43) Pub. Date: Sep. 1, 2016

(54) METHOD FOR PRODUCING A THERMOELECTRIC OBJECT FOR A THERMOELECTRIC CONVERSION DEVICE

(71) Applicant: Vacuumschmelze GmbH & Co. KG, Hanau (DE)

(72) Inventors: Michael MUELLER, Woerth (DE); Alberto BRACCHI, Hanau (DE)

(73) Assignee: Vacuumschmelze GmbH & Co. KG, Hanau (DE)

(21) Appl. No.: 15/053,403

(22) Filed: Feb. 25, 2016

(30) Foreign Application Priority Data
Feb. 26, 2015 (DE) 10 2015 102 763.1

(51) Int. Cl. H01L 35/34; B29C 43/00

(52) U.S. Cl. CPC H01L 35/34; B29C 43/006; B29L 2031/34

(57) ABSTRACT

A method is provided for producing a thermoelectric object for a thermoelectric conversion device in which a powder having a bulk density dₛ and elements in the ratio of a Half-Heusler alloy with a theoretical density dᵢ is provided. The powder is mechanically compressed and a green body with a tap density d_{K} is formed, the tap density d_{K} being up to 30% of the theoretical density dᵢ greater than the bulk density dₛ of the powder. The green body with the tap density d_{K} is sintered at a temperature of 1000° C. to 1500° C. for 0.5 h to 100 h, a thermoelectric object with a density dₛ of greater that 95% and preferably 99% of the theoretical density dᵢ being produced.

This application claims benefit of German Patent Application No. 102015102763.1, filed 26 Feb. 2015, the entire contents of which are incorporated herein by reference for all purposes.

### BACKGROUND

1. Field

The invention relates to a method for producing a thermoelectric object for a thermoelectric conversion device, in particular a method for producing a thermoelectric object made of a Half-Heusler alloy.

2. Description of Related Art

Thermoelectric conversion devices use the Seebeck effect to obtain electricity from heat that is typically wasted. A precondition of the widespread application of the thermoelectric effect to convert heat into electrical energy is the availability of efficient thermoelectric materials.

The efficiency of a thermoelectrical material is described by its ZT value, defined as ZT=T S²σ/κ where T is the absolute temperature, S the Seebeck coefficient, a the electric conductivity and κ the thermal conductivity. Half-Heusler alloys are regarded as a class of materials with promising potential for high ZT values. For example, U.S. Pat. No. 7,745,720 B2 discloses Half-Heusler alloys for thermoelectric conversion devices.

Half-Heusler alloys are intermetallic compounds with the general formula XYZ with an ordered cubic C1_{b} crystal structure. The transition metals X and Y and a main-group metal Z each occupy one of three nested face-centred cubic (fcc) sub-lattices. A fourth fcc sub-lattice is unoccupied. If the sum of the valence electrons in this structure is 18, the compounds demonstrate a semi-conducting behaviour.

Half-Heusler alloys based on the XNiSn and XCoSb systems (X=Zr, Hf, Ti) are of interest for thermoelectric applications because they have high Seebeck coefficients and high electrical conductivity values. However, they also have relatively high thermal conductivity values. This limits the ZT values of purely ternary compounds.

To increase the ZT value of Half-Heusler alloys it is possible to modify their properties in a specific manner by making substitutions in all three sub-lattices. One example is the compound TiNiSn in which the thermal conductivity is reduced and the electrical conductivity is increased by substituting Hf and Zr in the Ti location and Sb in the Sn location.

Suitable production methods are desirable to provide practical thermoelectric objects for thermoelectric conversion devices.

### SUMMARY

One object of the invention is therefore to provide a method for producing thermoelectric objects with which thermoelectric objects can be produced on an industrial scale.

A method is provided for the production of a thermoelectric object for a thermoelectric conversion device comprising the following. A powder with a bulk density d_{S} is provided which comprises elements in the ratio of a Half-Heusler alloy described by the formula αβχ and having a theoretical density dᵢ, where α is one or more of the elements in a group comprising Ti, Zr and Hf, β is Co or Ni and χ is Sn and/or Sb, the composition being described by ZrₐHf_{b}Ti_{c}NiSn_{1-d}Sb_{d} or ZrₐHf_{b}Ti_{c}CoSb₁₋ₑSnₑ, where 0≦a≦0.8, 0≦b≦0.8, 0≦c≦0.8, 0≦d≦0.1 and 0≦e≦0.3 and the sum (a+b+c) is 1. The powder is mechanically compressed to form a green body with a tap density d_{K}. The tap density d_{K} is up to 30% of the theoretical density dᵢ higher than the bulk density dₛ of the powder. The green body with tap density d_{K} is sintered at a temperature of 1000° C. to 1500° C. for 0.5 h to 100 h producing a thermoelectric object with a density d_{G} of greater than 95% and preferably 99% of the theoretical density dᵢ.

In this specification the terms ‘tap density’, ‘bulk density’, ‘density’, etc. denote relative density in relation to the theoretical density dᵢ. The thermoelectric object consequently has a density greater than 95% and preferably greater than 99% of the theoretical density.

In this specification the theoretical density dᵢ of the Half-Heusler alloy is defined as the theoretical density of the unit cell of the Half-Heusler alloy calculated using the mass content of the unit cell and its volume.

In this specification the bulk density d_{S} (or apparent density or pouring density) of the powder is defined as the mass of a specific volume of the powder poured in a specific manner.

In this specification the tap density d_{K} is defined as the mass of the volume unit of a green body produced by purely mechanical compression of the powder. An increase in density of the green body of less than 30% of the theoretical density dᵢ is achieved by mechanical compression, i.e. according to an embodiment of the invention d_{K}≦d_{S}+3dᵢ/10.

The bulk density and the tap density of a powder are dependent on grain size D₅₀ and grain size distribution. It is, for example, possible to achieve bulk densities of 20 to 40% of the theoretical density and tap densities of 35 to 65% of the theoretical density.

By contrast, a higher increase in density in the green body is achieved with conventional cold pressing processes, e.g. an increase of above 30% of the theoretical density.

According to an embodiment of the invention, however, the powder is not pre-compressed using a traditional cold pressing method or a hot pressing method but is rather compressed using mechanical compression alone to a tap density, which is lower than the density achieved following a pressing process. Examples of mechanical compression processes are tapping, shaking and/or vibration. The green body with these lower tap densities is sintered. Despite the lower density of the green body before the sintering process, it is nevertheless possible to achieve a density greater than 95% and even greater than 99% of the theoretical density in the sintered condition.

It is therefore possible to produce thermoelectric objects on an industrial scale and more economically using the method according to an embodiment of the invention since a high pressure pressing process is omitted. As a result, a plurality of green bodies can be formed simultaneously using simple mechanical compression as the serial pressing of a plurality of individual green bodies or simultaneous pressing of a plurality of green bodies is avoided. Moreover, the method is suitable for the production of objects with small dimensions, e.g. a few millimetres, such as a thin sheet or disc, or for a multiplicity of working components, such as legs, are required in a thermoelectric conversion device.

The powder contains elements in the ratios from which the composition of a Half-Heusler alloy can be formed. The powder can therefore comprise a Half-Heusler alloy or the starting material for forming a Half-Heusler alloy or precursor products of a Half-Heusler alloy.

The ideal stoichiometry of 1:1:1 is denoted by the formula αβχ. In practice, however, variations from this ideal stoichiometry of, for example, up to ±10%, can be present. In this specification these variations are included in the formula αβχ.

In theory, the sum of the valence electrons of a Half-Heusler alloy with a high thermoelectric effect is 18. In practice, however, variations from this value are possible and a range of 17.5 to 18.5 is therefore specified here.

In one embodiment a plurality of green bodies is formed simultaneously by mechanical compression and simultaneously sintered. This can be achieved by the use of a mould with a plurality of cavities in which the green bodies are formed from the powder and by sintering the mould with the plurality of green bodies formed within it.

For example, the powder can be introduced into a mould that has at least one cavity in which the green body is formed.

The powder in the mould can have a bulk density d_{S} where d_{S}≦40% of the theoretical density dᵢ. The powder can then be compressed mechanically to form a green body with the tap density. In some embodiments the powder is introduced into the mould continuously and compressed mechanically in order to fill the form with a green body with tap density d_{K}.

The mould can be coated with a release agent before the powder is introduced into it. This release agent can be used to remove the sintered object from the mould more easily.

The mould can comprise a ceramic or a refractory metal so that the mould is heat resistant up to the sintering temperature. The green body can thus be sintered in the mould.

The cross section of the cavity can have a clearance or inner dimension of w≦6 mm. The cross section of the cavity can be of different shapes, e.g. rectangular, in which case the cross section has a breadth and a depth, or circular in which case the cross section has a diameter, or hexagonal. A maximum value for the clearance is thus determined. Such dimensions can be used to produce legs of a thermoelectric conversion device, for example.

The cavity can have a height h and a cross-sectional area A where h≦0.2 √A. This cavity can be used for the production of thin sheets or thin discs or thin slices which can be processed to form a plurality of parts after sintering, for example.

The mould can have a plurality of cavities that are filled with the powder such that a plurality of green bodies can be formed at the same time by mechanical compression. The mould can have a honeycomb structure. The cavity or cavities can be open-ended such that the mould can be positioned on a separate plate or the cavity or cavities can have a base formed by the mould.

In this specification the terms ‘sintering method’ and ‘sintering’ denote a heat treatment used to achieve the sintering of grains that does not take place under a high external pressure. For example, the heat treatment takes place under an external pressure of less than 10 bar. Hot pressing processes are thus excluded as they exert high external pressure on the green body during heat treatment.

A sintering method also permits the object produced to be produced with dimensions close to those of its finished shape such that a practical working component for a thermoelectric conversion device can be made without, or with only minimal, further processing.

To form the green body, the powder can be introduced into a mould, the powder having a bulk density d_{S} of less than 30% of the theoretical density, and then mechanically compressed by means of tapping, shaking, vibration, ultrasound, etc. to increase the density by a maximum of 30% of the theoretical density.

The mechanical compression of the powder can take place in a protective atmosphere such as argon, nitrogen or a hydrogenous atmosphere, for example, or in a vacuum.

The mould can be made of a high-temperature-resistant and inert material or a combination of such materials. The powder is sintered in the mould. The term ‘high-temperature-resistant’ denotes in particular that the mould remains dimensionally stable in a temperature range above 1000° C., e.g. up to 1400° C. The term ‘inert’ denotes that the mould either does not react with the Half-Heusler alloy or reacts only to a technically tolerable extent even in a high temperature range above 1000° C.

Depending on the composition of the Half-Heusler alloy potential reactions, and therefore the selection of suitable materials, can vary. Suitable materials can, for example, be ceramics such as oxide ceramics, e.g. aluminium oxide or zirconium oxide, non-oxide ceramics, e.g. silicon nitride or silicon carbide, or silicate ceramics, e.g. a mullite such as C620 or an alumina porcelain such as C130. However, metals, in particular refractory metals such as molybdenum, wolfram and tantalum, can also be suitable.

The powder can be introduced into the mould continuously and compressed mechanically to avoid the formation of powder layers and pre-determined breaking points between the powder layers and to fill the mould with a powder of tap density.

Before the powder is introduced into the mould, it can be coated with a release agent. The release agent can assist in the removal of the green body from the mould after the sintering method and/or prevent an unwanted reaction between the Half-Heusler alloy and the mould.

In addition to mechanical compression, the powder can also be pressed at a pressure of less than 10 MPa. This can be achieved by means of an object of a specific weight, for example, being placed on the powder.

In some embodiments one or more additives are mixed into the powder. The additive can be used to improve the flow properties of the powder, thereby allowing a higher tap density to be achieved. Additives such as a stearate, a fatty acid and/or a liquid organic solvent can be used.

The tap density can also be improved by adjusting the particle size. In one embodiment the powder has a particle size D₅₀ of 6 μm to 150 μm or 6 μm to 10 μm. The powder can also have multimodal particle size distribution. The powder can, for example, be a mixture of two parts, a first having a particle size D₅₀ of 100 μm to 150 μm and a second having a particle size D₅₀ of 2 μm to 10 μm.

A plurality of green goodies can be mechanically compressed and sintered simultaneously. The mould can, for example, contain a plurality of channels with one green body being formed in each channel.

The powder can be produced using the following method. A starting material with elements in the ratio of a Half-Heusler alloy is melted and then cast to form an ingot. The ingot is heat treated at a temperature of 1000° C. to 1200° C. for 0.5 h to 100 h and preferably for 12 h to 24 h, in order to produce a homogenised ingot. The homogenised ingot is crushed and ground to form the powder.

The heat treatment used to produce the homogenised ingot can increase the purity of the Half-Heusler alloy, so that further, non-Half-Heusler alloy phases can be reduced. Moreover, this heat treatment of the ingot can have an effect on the lower limit of the sintering temperature which can be used to sinter the green body comprising the powder obtained from the ingot to a high density. The sintering temperature and the duration of the sintering process, in particular, can be reduced if the homogenisation heat treatment of the ingot takes place at a temperature in excess of 1000° C. A lower sintering temperature can reduce production costs because the electricity consumption of the sintering process is reduced due to the lower sintering temperature.

In one embodiment the starting material used to produce the ingot has a weight of at least 5 kg. The ingot can be crushed and ground to form a powder in several steps. The ingot can be crushed using a jaw crusher, for example. The crushed ingot can be ground in a mill to produce a coarse powder. After being ground to a coarse powder, part of the powder may build up in a sieve in the mill. This part of the powder is ground in a further grinding process. These steps may be repeated as many times as desired until the mean particle size of the powder is reduced to a pre-determined desired value. In a method of this type all the material can be provided in powder form with a desired maximum particle size. The coarse powder can be produced by means of a disc mill, for example.

In a further embodiment, the ingot is crushed to form a coarse powder and this coarse powder is ground to a fine powder in a further grinding process. This process can further reduce the particle size. The fine powder can be produced by means of a planetary ball mill or a jet mill.

In one embodiment, after milling, the coarse powder and the fine powder are mixed. The mixing can be used to homogenise the fine powder and/or its composition. The mixing may involve rotation, translation and inversion.

The starting material may be melted by means of vacuum induction melting (VIM). A vacuum induction melting process allows a large volume of starting material to be melted in one melting process and is therefore suitable for industrial-scale processes. The starting material can also be produced by means of rapid solidification technology or a powder atomization process.

The ingot may be homogenised at a temperature of at least 1000° C. for 0.5 to 100 hours under a protective gas or a vacuum. This heat treatment can be carried out in such a manner as to increase the proportion of the Half-Heusler alloy in the ingot. The heat treatment conditions can be selected such that following homogenisation no foreign phase reflexes are visible in a 0-20 x-ray diagram. In a further embodiment the ingot is heat treated at a temperature of 1050° C. to 1180° C. for 1 h to 24 h to homogenise the ingot.

The ingot and/or the green body can be heat treated and/or sintered under protective gas or a vacuum. Argon, helium, hydrogen or forming gas, for example, can be used as the protective gas. A protective gas and a vacuum both prevent the ingot and/or the green body from oxidising.

The sintering temperature can also be set according to the composition of the Half-Heusler alloy. For example, the sintering temperature is dependent on the titanium content. A suitable sintering temperature for a composition without titanium is approx. 1400° C. A suitable sintering temperature for a composition with a high titanium content is lower, e.g. approx. 1200° C.

The object produced using the method set out above can have a shape that is suitable as a working component for a thermoelectric conversion device. Alternatively, the object can be processed further to produce a working component. In one embodiment the thermoelectric object is processed to form a plurality of working components by means of sawing and/or grinding processes.

The sawing process can be carried out by means of wire sawing, inner diameter (or annular) sawing, wire cutting, water jet cutting and/or laser cutting. The grinding process can be carried out by means of disc grinding, twin-disc grinding, belt grinding and/or using a surface grinding machine.

In summary, the method provided enables powder comprising Half-Heusler alloys to be processed completely into dense moulded bodies without pressing. This is achieved by first introducing the powder into a mould. The fill density of the powder when introduced into the mould, referred to as the bulk density, can be significantly less than 30%, e.g. 20%. The powder is then mechanically pre-compressed in the mould by vibration, tapping, shaking or a similar method. The resulting fill density, now referred to as the tap density, can therefore be increased to 40% or more. In a subsequent sintering step this pre-compressed but unpressed powder can now be sintered in the mould in a temperature range of 1000° C. to 1500° C. for 0.5 h to 24 h under a protective gas or a vacuum to form a dense body, i.e. an object with a density of at least 95% of the theoretical density.

By using vibration/tapping/shaking or similar methods to pre-compress the powder in a mould, the powder can also be introduced into very small moulds reliably and simply. As a result it is possible to produce by simple means legs of smaller dimensions than those produced using production processes in which a higher pressure is used to produce a green body.

### BRIEF DESCRIPTION OF THE DRAWINGS

Specific embodiments and examples are explained in further detail below with reference to the drawings.

FIG. 1 illustrates a diagram of the tap density d_{K} for powders of different bulk densities dₛ,

FIG. 2 illustrates a flow diagram of a method for producing a thermoelectric object,

FIG. 3 illustrates a schematic view of a method for producing a thermoelectric object, and

FIG. 4 illustrates a schematic view of a method for producing a thermoelectric object.

### DETAILED DESCRIPTION OF THE SPECIFIC EMBODIMENTS

Various procedures for producing a thermoelectric object suitable for a thermoelectric conversion device are described below, the processing methods used being suitable for industrial-scale processes. The powder is mechanically pre-compressed and then sintered without using a cold- or hot-pressing process. These sintered samples can be used as thermoelectric components in thermoelectric conversion devices.

A plurality of probes is preferably produced at the same time. In particular, the powder can be introduced into a plurality of cavities in a mould, mechanically compressed and then sintered. As the powder is not pressed but merely mechanically compressed, it is possible to produce a plurality of samples economically without using a pressing device for a plurality of blanks side by side.

The powder can be produced from a cast ingot. For example, a starting material with the desired composition of a Half-Heusler alloy can be melted by means of vacuum induction melting (VIM) and then cast to form an ingot. The ingot produced in this manner is crushed and ground in a plurality of steps in order to produce a powder from the ingot.

TABLE 1

| | | | | Tap | Ex. press |
|---|---|---|---|---|---|
| Ex. | Composition | Grain size | Bulk density | density | density |
| 1 | Zr_{0.5}Hf_{0.5}CoSb_{0.8}Sn_{0.2} | D₅₀ = 2.1 μm | 40% | 40% | 62% @2 t/cm² |
| 2 | Ti_{0.5}Zr_{0.25}Hf_{0.25}NiSn | D₅₀ = 3 μm | 21% | 42% | 61% @2.1 t/cm² |
| 4 | Ti_{0.5}Zr_{0.25}Hf_{0.25}NiSn | D₅₀ = 8 μm | 28% | 52% | 65% @2 t/cm² |
| 13 | Ti_{0.5}Zr_{0.25}Hf_{0.25}NiSn | D₅₀ = 140 μm | 40% | 63% | 71% @2.7 t/cm² |

Table 1 indicates the particle size, bulk density dₛ, tap density d_{K} and compressed density d_{P} for four examples of powders. The values show that particle size has an influence on bulk density and tap density. A high tap density is desirable in order to minimise shrinkage during sintering.

FIG. 1 illustrates a diagram that gives a graphic representation of the increase in the density of the powder starting from the bulk density d_{S} due to pressing or mechanical compression. Using mechanical compression alone the density is increased from the bulk density d_{S} by less than a further 30% of the theoretical density. Using a pressing process the density is increased from the bulk density d_{S} by at least a further 30% of the theoretical density.

Higher tap densities in the green body can also be achieved by the use of one or more of the following measures.

It is possible to achieve a higher density with pre-compression using coarser powders. For example, using a powder with a median particle size d₅₀ of d₅₀=3 μm it is possible to achieve a tap density of 42%. When using a coarser powder of d₅₀=8 μm and otherwise identical conditions a tap density of 52% is achieved. With a still coarser powder of d₅₀=140 μm the tap density is increased further to 63%. As the sinterability of coarse powders generally decreases and higher sintering temperatures, for examples, are therefore required, it is possible to achieve a compromise between high tap density and good sinterability using mixtures of coarse and fine powders.

Additions to the powder can improve its flow characteristics and thereby achieve higher tap densities. These additives can be solids or liquids. Suitable solids include stearates, such as zinc stearate or magnesium stearate, or fatty acids such as stearic acid. Liquid additives can, in particular, be organic solvents such as alcohols, e.g. ethanol, isopropanol; ketones e.g. acetone, methylethylketone; or fatty acids e.g. caproic acid, isostearic acid. These additives have the further effect of improving the handling characteristics of the powders. They work as binding agents and so reduce the creation of powder dust during processing.

During mechanical compressions a light pressure can additionally be exerted on the powder by tapping, shaking, vibration or a similar method, thereby increasing the tap density further. Here the term low pressure means a pressure significantly lower than that generally used in the production of green bodies using die pressing, e.g. less than 10 MPa. The low pressure can be created by placing a weight on the powder, for example.

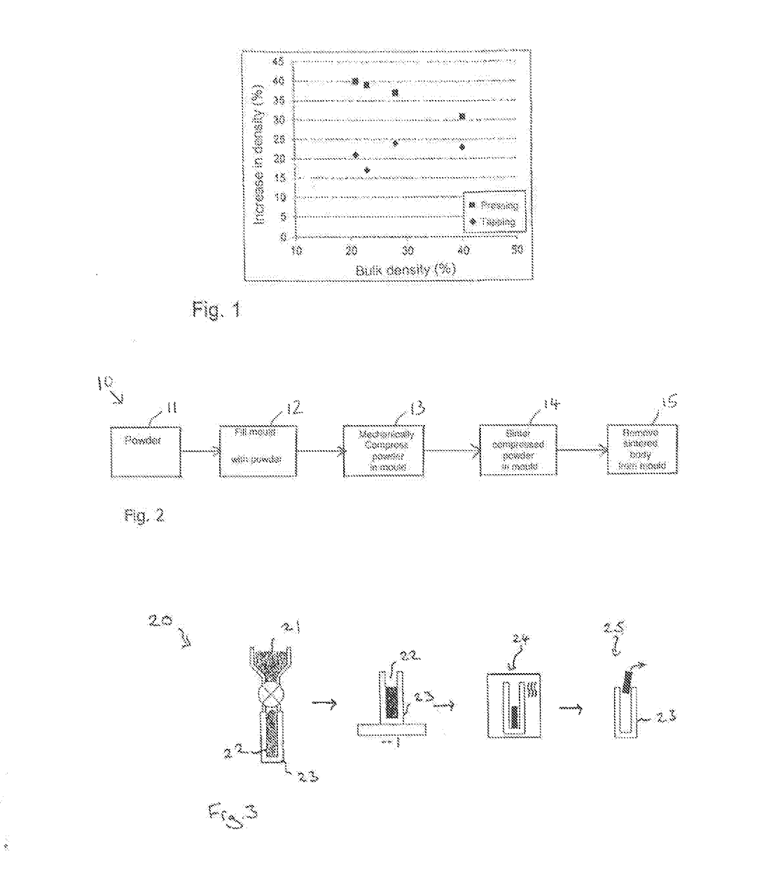

FIG. 2 illustrates a flow diagram of a method 10 for producing a plurality of thermoelectric objects such as legs for a thermoelectric conversion device in which only one of the objects is illustrated.

The powder is provided at step 11 and introduced into a mould at step 12 so that the mould is filled with powder to a bulk density d_{S}. At step 13 the powder is mechanically compressed in the mould, thereby achieving a tap density d_{K} that is no more than 30% of the theoretical density dᵢ greater than the bulk density d_{S}. The powder is mechanically compressed both laterally and vertically by shaking, vibration, tapping, etc. in order to create a green body with a tap density d_{K}. Without being subject to a further pressing process, the mechanically compressed powder or green body is sintered in the mould at step 14 and then removed from the mould with a density of 95% to 99% of the theoretical density dᵢ at step 15.

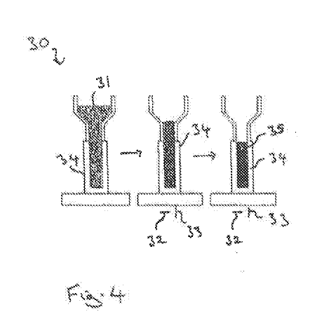

FIG. 3 illustrates a schematic view of a method 20 for producing one of a plurality of thermoelectrical objects. The powder 21 is introduced into the cavities 22 of a mould 23 such that the cavities 22 are almost completely filled with the powder 21 with a bulk density d_{S}.

The powder 21 is mechanically compressed in the mould 23 so as to achieve a tap density d_{K} no more than 30% of the theoretical density dᵢ higher than the bulk density d_{S}. The cavity 22 is now no longer almost full of the powder 21. At step 24 the mechanically compressed powder or green body is sintered in the mould 23 without being subject to a further pressing process, the external diameters of the object being reduced in comparison to the green body. At step 25 the object is then removed from the mould 23 with a density of 95% to 99% of the theoretical density dᵢ.

FIG. 4 illustrates a schematic view of a method 30 for producing one of a plurality of thermoelectric objects. In the method 30 the powder 31 is gradually introduced into the mould 34 during mechanical pre-compression as indicated graphically by arrows 32, 33 so that the cavities 35 of the mould 34 are almost complete filled with the powder 31 with the tap density d_{K}. The mould 34 is then subject to heat treatment, the powder being sintered and the density of the powder being increased from the tap density d_{K} to a density d_{G} of at least 95% of the theoretical density dᵢ.

The powder can be mechanically pre-compressed in a mould. If the mould is designed such that it takes all of the powder at a bulk density d_{S}, compression to the tap density d_{K} creates a free volume in the mould as illustrated in FIG. 3. When compressed from 20% to 40% the free volume can therefore be 50%, for example. If the powder is sintered in the mould, however, the available sinter furnace capacity is not fully exploited.

In one embodiment the powder is therefore fed in via a feeder during pre-compression. The amount of powder fed in can be metered such that the mould is completely full when the tap density is reached, thereby avoiding unused free capacity as shown in FIG. 4.

If the pre-compressed powder is sintered to form a dense body, both volume and length are also both wasted. In case of isotropic shrinkage, the length of a fully sintered powder with a tap density of 40% lost can be approx. 26% in all spatial directions. The high level of shrinkage can result in undesired effects such as deformation of the moulded parts such that they no longer correspond to the required tolerances in terms of geometry. This loss of volume also restricts sinter furnace configuration as a larger furnace volume is required for a given final volume of moulded parts. These effects can be prevented or minimised by pre-compressing the powder to the highest possible degree, e.g. 50% or more.

The mould in which the powder is sintered can have a plurality of channels. The cross section of the channels can be of any shape including, for example, a square, rectangular, round or hexagonal cross section. The dimensions of the channel cross sections are selected such that, following deduction of the volume lost during sintering, the lateral dimensions of the moulded bodies sintered in them correspond to the desired final dimensions as required, for example, for use as elements in thermoelectric modules.

The thickness of the mould walls between the channels can be small. A small wall thickness means on average less than or equal to 1 mm or less than or equal to 0.7 mm. A small wall thickness makes it possible to achieve a high channel packing density in the mould.

The height of the channels and the tapping-in height of the powder can be set such that the height of the moulded body after sintering corresponds with a small allowance, for example on average 200 μm or 300 μm, to the desired final dimension. The height of the elements can be adjusted exactly after sintering by means of a grinding process.

However, the height of the channels and the tapping-in height of the powder can also be set such that the height of the moulded body after sintering is a multiple of the final height of the elements. The rods thus obtained can be processed to form a multiplicity of elements by means of cutting processes.

In a further embodiment the mould or parts of it are coated with a release agent. The release agent reduces the danger of a reaction between the Half-Heusler powder and the mould and of the moulded body adhering to the mould during sintering. Suitable release agents include, for example, powders of stable oxides such as aluminium, titanium, zirconium and hafnium oxide and rare earth oxides such as neodymium oxide. The release agent powder can be applied mixed with organic solvents in the form of a paste with the solvent subsequently being removed again by means of a drying process.

In one embodiment the mould can also be made of a material that, rather than being dimensionally stable or inert up to a lower temperature, e.g. 1100° C., is only dimensionally stable or inert up to the sintering temperature. In this case the moulded body is sintered in two steps. At the first step the powder and the mould are heated to a temperature at which the mould is sufficiently dimensionally stable and insert, e.g. 1100° C. This heat treatment partially sinters the Half-Heusler powder, giving the powder sufficient dimensional stability. As a result the powder can be removed from the mould at the next step and be sintered without a mould to form a dense moulded body at a higher temperature, e.g. at 1200° C. to 1500° C.

### Example 1

By melting the elements an ingot of the Half-Heusler compound Zr_{0.5}Hf_{0.5}CoSb_{0.8}Sn_{0.2} is produced by means of vacuum induction melting. The ingot is processed by grinding in a disc or planetary ball mill to form a powder with a median particle size distribution of D₅₀=2.1 μm. The powder is poured into a cylindrical mould made of aluminium oxide with an internal diameter of 5.1 mm and a height of 50 mm reaching a fill density of 23%. The powder is pre-compressed to 40% by tapping. The powder is then sintered at 1360° C. for four hours in a vacuum of 10⁻² mbar. This gives a more compact sintered body with a diameter of 3.8 mm and a height of 20 mm. The density of the sintered body is 99.4% of the maximum density of 9.3 g/cm³.

### Example 2

An ingot of the Half-Heusler compound Ti_{0.5}Zr_{0.25}Hf_{0.25}NiSn produced by means of vacuum induction melting is aged at 1050° C. for 24 hours under argon. It is then processed to form a powder with a median particle size distribution of D₅₀=3 μm. 38 g of the powder are poured into a square mould made of aluminium oxide with an edge length of 36 mm. The mould is pre-coated with neodymium oxide powder as a release agent. The powder is pre-compressed to 42% using a vibration plate and then sintered in the mould at 1230° C. for 4 hours in a vacuum. This produces a square sintered body with an edge length of 27 mm and a height of 6.3 mm. The density of the sintered body is 99.9% of the maximum density of 8.3 g/cm³.

### Example 3

In Example 3 a ceramic honeycomb body consisting of a multiplicity of channels open on both sides, in particular 12×12×144 channels, with a square cross section of 3 mm edge length and height 41 mm is used as the mould. The wall thickness between the channels is 0.7 mm. The material used for the honeycomb body is mullite C620 (30% SiO₂, remainder Al₂O₃). A molybdenum plate serves as the base of the mould. In addition, the base plate is coated with a neodymium oxide powder as a release agent. Powder with a composition of Ti_{0.5}Zr_{0.25}Hf_{0.25}NiSn with D₅₀=3 μm is poured into the mould via a feeder whilst being tapped. This allows the channels to be filled completely with simultaneous pre-compression of the powder to 42%. The powder is sintered in the mould at 1250° C. for four hours to obtain dense, rod-shaped sintered bodies with a mean cross section of 2.25 mm×2.25 mm and a height of 30 mm.

### Example 4

Sintered bodies with the composition Ti_{0.5}Zr_{0.25}Hf_{0.25}NiSn are produced in the mould described in Example 1 above. This time, however, the compound is ground to form a coarse powder with D₅₀=8 μm and the powder is mixed with 0.1% by weight isopropanol. The powder is once again tapped into the mould via a feeder, thereby filling the channels completely with powder pre-compressed to 52%. After tapping in, the isopropanol is removed by vacuum drying, i.e. vaporizing under a vacuum of 10⁻¹ to 10⁻² mbar. The powder is then sintered in the mould at 1270° C. for four hours. The resulting rod-shaped sintered bodies have a mean square cross section of 2.42 mm×2.42 mm and a height of 33 mm.

### Example 5

Dense, rod-shaped sintered bodies are produced as described in Examples 3 and 4, the honeycomb body used as the mould this time consisting of alumina porcelain C130 (43% SiO₂, remainder Al₂O₃). The results achieved with this mould are the same as those reported in Examples 3 and 4.

### Examples 6 to 12

Half-Heusler alloys of various compositions are melted by means of vacuum induction melting and the ingots are processed to form a powder. The powders are mixed with 0.2% by weight of different organic solvents. The powders are poured into cylindrical moulds made of aluminium oxide with internal diameters of 5.1 mm and heights of 50 mm and pre-compressed by tapping. The organic additives are then removed again by vacuum drying and the powder is sintered I the moulds. The process conditions and densities achieved for examples 6 to 12 are set out in Table 1 below.

TABLE 1

| | | D₅₀ | | Sintering | Density |
|---|---|---|---|---|---|
| No. | Composition | (μm) | Additive | conditions | achieved |
| 6 | Ti_{0.5}Hf_{0.5}CoSb_{0.8}Sn_{0.2} | 2.6 | Ethanol | 1340° C. | 99.5% of |
| | | | | 4 h | 9.0 g/cm³ |
| | | | | vacuum | |
| 7 | Ti_{0.2}Hf_{0.8}CoSb_{0.8}Sn_{0.2} | 4 | Acetone | 1370° C. | 99.5% of |
| | | | | 4 h | 9.7 g/cm³ |
| | | | | vacuum | |
| 8 | Ti_{0.5}Zr_{0.5}CoSb_{0.8}Sn_{0.2} | 4.5 | Isostearic acid | 1360° C. | 99% of |
| | | | | 1 h argon | 7.8 g/cm³ |
| 9 | Ti_{0.25}Zr_{0.5}Hf_{0.25}CoSb_{0.8}Sn_{0.2} | 2.5 | Methylethylketone | 1360° C. | 99% of |
| | | | | 4 h argon | 8.6 g/cm³ |
| 10 | Zr_{0.4}Hf_{0.6}NiSn_{0.98}Sb_{0.02} | 6 | Isopropanol | 1380° C. | 97% of |
| | | | | 2 h helium | 9.6 g/cm³ |
| 11 | Ti_{0.5}Zr_{0.425}Hf_{0.425}NiSn | 2.9 | Acetone | 1270° C. | 98% of |
| | | | | 8 h | 8.9 g/cm³ |
| | | | | vacuum | |
| 12 | Ti_{0.7}Zr_{0.15}Hf_{0.15}NisSn | 3.5 | Methylethylketone | 1230° C. | 99% of |
| | | | | 4 h | 7.8 g/cm³ |
| | | | | vacuum | |

### Example 13

A further example demonstrates the use of powders clearly coarser than those employed in the preceding examples. An ingot with the Half-Heusler composition Ti_{0.5}Zr_{0.25}Hf_{0.25}NiSn is processed to form a powder by means of a disc mill. The upper limit of the particle size is set at 315 μm by sieving, giving a median particle size of D₅₀=140 μm.

The powder is mixed with 0.7% by weight isopropanol and poured into a cylindrical mould made of aluminium oxide with a diameter of 5.1 mm to give a bulk density of 40%. The powder is then pre-compressed to a tap density of 63% and the isopropanol is removed by vacuum drying. Sintering takes place in the mould at 1320° C. for eight hours under a vacuum. This method allows sintered bodies to be produced with a mean diameter of 4.4 mm and 95.5% of the theoretical density.

### Example 14

The coarse powder with D₅₀=140 μm from Example 13 is mixed with 20% fine powder of the same composition Ti_{0.5}Zr_{0.25}Hf_{0.25}NiSn. The powder mixture including 0.2% by weight isopropanol can be pre-compressed in the mould made of aluminium oxide to a tap density of 60%. Following vacuum drying, it is sintered as in Example 13 at 1320° C. for eight hours under a vacuum. This method produces sintered bodies with a density of 98% of the theoretical density.

1. A method for producing a thermoelectric object for a thermoelectric conversion device comprising:
providing a powder with a bulk density dₛ comprising elements in the ratio of a Half-Heusler alloy that is described by the formula αβχ and has a theoretical density dᵢ, α being one or more of the elements in the group consisting of Ti, Zr and Hf, β being Co or Ni, χ being Sn and/or Sb, the composition being described by ZrₐHf_{b}Ti_{c}NiSn_{1-d}Sb_{d} or ZrₐHf_{b}Ti_{c}CoSb₁₋ₑSnₑ, where 0≦a≦0.8, 0≦b≦0.8, 0≦c≦0.8, 0≦d≦0.1 and 0≦e≦0.3 and the sum (a+b+c)=1,
mechanically compressing the powder, wherein a green body with a tap density d_{K} is formed, the tap density d_{K} being up to 30% of the theoretical density dᵢ higher than the bulk density dₛ of the powder,
sintering the green body with tap density d_{K} at a temperature of 1000° C. to 1500° C. for 0.5 h to 100 h, wherein a thermoelectric object with a density d_{G} greater than 95%, preferably greater than 99%, of the theoretical density dᵢ is produced.

2. A method for producing a thermoelectric object for a thermoelectric conversion device comprising:
providing a powder with a bulk density dₛ comprising elements in the ratio of a Half-Heusler alloy that is described by the formula αβχ and has a theoretical density dᵢ, α being one or more of the elements in the group consisting of Sc, Ti, V, Cr, Mn, Y, Zr, Nb, La, Hf, Ta and one or more of the rare earth elements, β being one or more of the group consisting of Fe, Co, Ni, Cu and Zn, χ being one or more of the group consisting of Al, Ga, In, Si, Ge, Sn, Sb and Bi, and the sum of the valence electrons lying between 17.5 and 18.5,
mechanically compressing the powder, wherein a green body with a tap density d_{K} is formed, the tap density d_{K} being up to 30% of the theoretical density dᵢ higher than the bulk density dₛ of the powder,
sintering the green body with tap density d_{K} at a temperature of 1000° C. to 1500° C. for 0.5 h to 100 h, wherein a thermoelectric object with a density d_{G} greater than 95%, of the theoretical density dᵢ is produced.

3. A method in accordance with claim 1, wherein a plurality of green bodies is formed simultaneously by mechanical compression and simultaneously sintered.

4. A method in accordance with claim 1, wherein the powder is introduced into a mould and the powder in the mould has a bulk density dₛ where dₛ≦40% of the theoretical density dᵢ.

5. A method in accordance claim 4, wherein the powder is introduced continuously into the mould and compressed mechanically in order to fill the mould with a green body with a tap density d_{K}.

6. A method in accordance with claim 4, wherein the mould is coated with a release agent before the powder is introduced into it.

7. A method in accordance with claim 4, wherein the mould comprises a ceramic or a refractory metal.

8. A method in accordance with claim 4, wherein the green body is sintered in the mould.

9. A method in accordance with claim 4, wherein the mould comprises at least one cavity in which the green body is formed.

10. A method in accordance with claim 9, wherein the cross section of the cavity has a clearance w≦6 mm.

11. A method in accordance with claim 9, wherein the cavity has a height h and a cross-sectional area A, where h≦0.2 √A.

12. A method in accordance with claim 4, wherein the mould comprises a plurality of cavities that are filled with the powder, and a plurality of green bodies are formed simultaneously by mechanical compression.

13. A method in accordance with claim 1, wherein the powder is compressed mechanically by means of tapping, shaking, vibration and/or ultrasound.

14. A method in accordance with claim 1, wherein the powder is further pressed at a pressure of less than 10 MPa during the mechanical compression.

15. A method in accordance with claim 1, wherein one or more additives are mixed into the powder.

16. A method in accordance with claim 15, wherein a stearate, a fatty acid and/or a liquid organic solvent is mixed in as the additive.

17. A method in accordance with claim 1, wherein the powder has a particle size D₅₀ of 6 μm to 150 μm.

18. A method in accordance with claim 1, wherein the green body is sintered in two steps and the green body is removed from the mould before the second step.

19. A method in accordance with claim 18, wherein the green body is heat treated at a temperature of 1000° C. to 1200° C. in a first step and sintered at a temperature of 1200° C. to 1500° C. in a second step.

20. A method in accordance with claim 1, wherein the green body is sintered under protective gas or a vacuum.

21. A method in accordance with claim 1, wherein the powder is compressed under protective gas or a vacuum.

22. A method in accordance with claim 1, wherein after sintering, the object has a cross section corresponding to that of the end cross section and the height of the object is adjusted by further processing.

23. A method in accordance with claim 1, further comprising:
melting a starting material comprising elements in the ratio of a Half-Heusler alloy and subsequently casting to form an ingot,
heat treating the ingot at a temperature of 1000° C. to 1200° C. for 0.5 h to 100 h to produce a homogenised ingot,
crushing the homogenised ingot,
milling the crushed ingot to form the powder.

24. A method in accordance with claim 23, wherein the ingot is processed to a powder in multiple stages.

25. A method in accordance with claim 24, wherein the ingot is crushed using a jaw crusher and then ground using a mill.

26. A method in accordance with claim 23, wherein the starting material is melted by means of vacuum induction melting.

27. A method in accordance with claim 1, wherein the powder is produced directly from a molten mass by a powder gas atomisation system.

28. A method in accordance with claim 1, wherein a starting material comprising elements in the ratio of a Half-Heusler alloy is melted, solidified using a rapid solidification technology and then ground to produce the powder.

29. A method in accordance with claim 2, wherein the Half-Heusler alloy comprises a composition of αNi_{1-y}β_{y}S_{1-z}χ_{z}, where α is one of more of the group comprising Zr, Hf and Ti, β is one or more of the group comprising Fe, Co, Cu and Zn and χ is one or more of the group consisting of Al, Ga, In, Si, Ge, Sn and Bi, where 0≦y≦0.9 and 0≦z≦0.3.

30. A method in accordance with claim 2, wherein the Half-Heusler alloy comprises a composition of αCo_{1-y}β_{y}Sb_{1-z}χ_{z}, where α is one of more of the group comprising Zr, Hf and Ti, β is one or more of the group comprising Fe, Ni, Cu and Zn and χ is one or more of the group consisting of Al, Ga, In, Si, Ge, Sn and Bi, where 0≦y≦0.9 and 0≦z≦0.3.

31. A method in accordance with claim 2, wherein the Half-Heusler alloy comprises a composition based on XNiSn or XCoSb, where X is one or more elements from the group comprising Zr, Hf and Ti.

32. A method in accordance with claim 31, wherein the Half-Heusler alloy comprises XNiSn and a proportion of the Sn being replaced by Sb.

33. A method in accordance with claim 31, wherein the Half-Heusler alloy comprises Ti and Zr and Hf.

34. A method in accordance with claim 2, wherein elements in the ratio 0.25 Zr:0.25 Hf:0.5 Ti:1 Ni:0.998 Sn:0.002 Sb or 0.5 Zr:0.5 Hf:1 Co:0.8 Sb:0.2 SB are provided as the starting material.

35. A method in accordance with claim 2, wherein the thermoelectric object produced has a density d_{G} greater than 99%.

36. A method in accordance with claim 1, wherein the powder has a particle size D₅₀ of 6 μm to 10 μm.
